(19) United States
(12) Patent Application Publication
(10) Pub. No.: US 2004/0016635 A1
(43) Pub. Date: Jan. 29, 2004

(54) Monolithic sputtering target assembly

(76) Inventors: Robert B. Ford, Court House, OH (US); Christopher A. Michaluk, Gilbertsville, PA (US)

Correspondence Address: Martha Ann Finnegan, Esq., Cabot Corporation, 157 Concord Road, Billerica, MA, 01821-7001, US

(21) Appl. No.: 10/621,096

(22) Filed: Jul. 16, 2003

Related U.S. Application Data
(60) Provisional application No. 60/397,418, filed on Jul. 19, 2002.

(51) Int. Cl. C23C 14/34

(52) U.S. Cl. 204/192.1; 204/192.12; 204/298.13; 204/298.12

(57) ABSTRACT

A monolithic sputtering target assembly having a one piece assembly made from the same material is disclosed. Also disclosed are other sputtering target assemblies which have a backing plate and a sputtering target blank wherein the backing plate is made from or contains a metal, such as a valve metal, cobalt, titanium, or alloys thereof. Methods of recycling target assemblies are further disclosed as well as unique methods of providing target assemblies to fabricators.

This application claims the benefit under 35 U.S.C. §119(e) of prior U.S. Provisional Patent Application No. 60/397,418 filed Jul. 19, 2003, which is incorporated in its entirety by reference herein.

### BACKGROUND OF THE INVENTION

The present invention relates to sputtering targets and sputtering target assemblies as well as methods of making the same. The present invention further relates to methods of using and recycling sputtering targets and sputtering target assemblies.

In the sputter application field, typically a sputtering target assembly has a sputtering target and a backing plate. For instance, a metal target or metal target blank is bonded onto a backing plate, such as a backing plate flange assembly typically made of copper, aluminum, or alloys thereof. This bonding process and construction of the target assembly not only adds cost to the overall assembly, it also adds weight and creates the risk of having a target assembly de-bond while in use. This de-bonding risk is even more possible due to the continuing progression of the industry to use larger and larger targets. Compounding the problem are dissimilar coefficients of thermal expansion of the target material and backing plate material which can cause such disadvantages as the warping of the assembly during use which affects performance.

In addition, since typically the backing plate is made of copper or aluminum there is a risk of contamination caused by these materials being present with the target material. Also, due to the backing plate being made of copper or aluminum, which typically is dissimilar to the target material, many times the backing plate receives a coating in order to camouflage or conceal the copper or aluminum backing plate in an attempt to control contamination issues and the like. However, such a coating can be quite expensive and adds extra time to fabricating the target assembly and furthermore does not fully ensure that contamination will be controlled since this coating may not be uniformly applied or be thick enough in order to resist the sputtering process.

### SUMMARY OF THE PRESENT INVENTION

A feature of the present invention is to provide a target assembly which avoids the de-bonding issue.

Another feature of the present invention is to extend the target life of a sputtering target.

A further feature of the present invention is to provide a target assembly which avoids the high contamination risk that is present in conventional target assemblies.

A further feature of the present invention is to avoid the need for a coating on the backing plate in order to conceal the backing plate material.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a monolithic sputtering target assembly. The monolithic sputtering target assembly is a one piece assembly made from the same material, which is typically a metal.

The present invention further relates to a sputtering target assembly which contains a backing plate and a sputtering target blank. The backing plate is made from a metal such as a valve metal, cobalt, titanium, or an alloy thereof. The sputtering target blank is made from a metal. Preferably, with respect to the sputtering target assembly, the backing plate and the sputtering target blank are made from the same material.

The present invention also relates to a method of recycling sputtering target assemblies, and involves sputtering a sputtering target blank that is part of a monolithic sputtering target assembly to form a spent monolithic sputtering target assembly and then recycling the spent sputtering target assembly. The recycling can include, such processes as melting down the spent sputtering target assembly, forming a powder out of the spent sputtering target assembly, redepositing or otherwise reforming the spent sputtering target assembly into a monolithic sputtering target assembly, filling in the cavities of the spent sputtering target assembly, and the like.

Also, the present invention relates to a method of doing business which involves providing a monolithic sputtering target assembly to a fabricator where the target blank which is part of the monolithic sputtering target assembly is sputtered to form a spent monolithic sputtering target assembly. The process then involves determining the amount of target material consumed by the sputtering process and then charging the fabricator or other person for the actual amount of target material consumed during the sputtering process. This method of doing business can further include returning the spent monolithic target assembly back to the provider for further processing such as to recycle into a new monolithic sputtering target assembly and the like.

It is to be understood that both the foregoing general description and the following detailed description are exemplary and explanatory only and are intended to provide a further explanation of the present invention, as claimed.

The accompanying drawings, which are incorporated in and constitute a part of this application, illustrate several embodiments of the present invention and together with the description, serve to explain some of the principles of the present invention.

### BRIEF DESCRIPTION OF THE DRAWINGS

FIG. 1 is a cutaway view of a monolithic sputtering target assembly of the present invention.

FIG. 2 is a cutaway view of another monolithic sputtering target assembly of the present invention.

FIG. 3 is a side view of a monolithic sputtering target assembly. Other shapes and sizes are possible.

### DETAILED DESCRIPTION OF THE PRESENT INVENTION

The present invention relates to sputtering target assemblies which have unique advantages over conventional sputtering target assemblies. In more detail, in one embodiment of the present invention, the present invention relates to a monolithic sputtering target assembly. The monolithic sputtering target assembly has a one piece assembly or a one piece construction which is made entirely from the same material, which is preferably a metal which can be sputtered or eroded in a deposition process.

The term “monolithic” is with reference to the sputtering target assembly being made from a single piece. There are no joints or seams, in the target assembly, which are caused by the joining of separate pieces to form conventional target assemblies which bond the backing plate to the sputtering target blank to form the assembly. Another term that can be used to describe this embodiment is a uni-body target assembly.

The material used for the monolithic sputtering target assembly can be any metal which can be sputtered or eroded in a sputtering or deposition process. Preferably, the material for the monolithic sputtering target assembly is a valve metal such as tantalum or niobium or alloys thereof. Other examples of suitable materials include, but are not limited to, cobalt, titanium, aluminum, copper, tungsten, gold, silver, and alloys thereof. Other examples include Ta—W alloys, Ta—Nb alloys, Ta—Mo alloys, Ta—Ti alloys, Ta—Zn alloys, Nb—W alloys, Nb—Ta alloys, Nb—Mo alloys, Nb—Ti alloys, Nb—Hf alloys, Nb—Zr alloys, W, Re, Hf, Mo, V, Cr, Be, In, Sn, Au, Pt, Pd, Ag, Ir, Nd, Ce, Yb, Am, Cm, No, or alloys thereof. Oxides and nitrides of these above-mentioned materials can also be used, especially for powder-met portions.

The metal used to form the monolithic sputtering target assembly can be formed from a metal ingot or can be a powder-met type material. The ingot derived material is typically formed into a plate or billet or other shape and then appropriately deformed into the shape of a monolithic sputtering target assembly as described in more detail below. The powder-met material can be either formed into a plate or billet or other shape and subsequently deformed into the shape of a monolithic sputtering target assembly or the powder-met material can be properly consolidated into the shape of a monolithic sputtering target assembly. The consolidation can be by hot isostatic pressing, sintering, heat and pressure, or other conventional techniques to consolidate powder-met material. By using a powder-met material, essentially the monolithic sputtering target assembly can be formed in one consolidation step using a mold or similar shape forming device (in one embodiment), and then processed to a final target assembly by machining and other conventional processing steps. As further described below, in another embodiment, a monolithic sputtering target assembly can be formed wherein a portion of the sputtering target assembly is an ingot derived material and another portion of the sputtering target assembly is a powder-met material. For instance, the sputtering target blank can be an ingot derived material and the backing plate portion such as the flanges can be a powder-met material. Any combination is possible depending upon the desires of the end user.

The metal that is preferably used to form the monolithic sputtering target assembly can have any purity, can have any texture, and/or can have any grain size, or other properties. Preferably, the metal has a high purity such as from about 99% pure or less to about 99.995% or higher. One suitable example of such a high purity metal is tantalum or niobium such as those described in International Published Application Nos. WO 00/31310 and WO 01/96620, both of which are incorporated in their entirety by reference herein and form a part of the application. The material forming the monolithic sputtering target assembly can also have, as indicated, any texture, such as a mixed texture on the surface and/or throughout the entire thickness of the target assembly. For instance, the texture can be a (111) or a (100) texture which can be a primary texture. This texture can be predominantly on the surface and/or throughout the entire thickness of the target assembly. Thus, the metal can have a primary or mixed (111) texture or a primary or mixed (100) texture. Furthermore, the metal can have a primary or mixed (111) texture and a minimum (100) texture on the surface and/or throughout the thickness of the sputtering target assembly which is substantially void of (100) textural bands. In the opposite, the material used to form the target assembly can have a primary or mixed (100) texture, and a minimum (111) texture on the surface and/or throughout the thickness of the sputtering target assembly, which can be substantially void of (111) textural bands. Any textures can be used.

Furthermore, the material that forms the monolithic sputtering target assembly can preferably have a texture which is advantageous for sputtering end uses. The material preferably has a surface which when sputtered, the texture of the material leads to a sputtering target which is easily sputtered and very few if any areas in the sputtering target resist sputtering. Preferably, the sputtering of the sputtering target leads to a very uniform sputtering erosion thus leading to a sputtered film which is therefore uniform as well. Preferably, the material that is used to form the monolithic sputtering target assembly is at least partially recrystallized, and more preferably is at least about 80% recrystallized and even more preferably at least about 98% recrystallized and most preferably is fully recrystallized.

With respect to grain size, as indicated, any grain size can be present in the material forming the monolithic sputtering target assembly. Preferably, the material forming the monolithic sputtering target assembly has an average grain size of about 350 microns or less. Other ranges of acceptable average grain sizes include, but are not limited to, from about 10 microns or less to about 300 microns or more in average grain size; from about 10 microns to about 100 microns in average grain size; about 50 microns or less in average grain size; about 25 microns or less in average grain size; and the like. Furthermore, the material present in forming the monolithic sputtering target assembly can have any maximum grain size such as a maximum grain size of 350 microns or less. Other suitable maximum grain sizes include, but are not limited to, 300 microns or less; 100 microns or less; 50 microns or less; or 25 microns or less. It is to be understood that maximum grain size refers to the highest grain size detectable on the monolithic sputtering target assembly material and thus is quite different from an average grain size which refers to the overall average of detectable grain sizes present in the material forming the monolithic sputtering target assembly.

With respect to the shape of the monolithic sputtering target assembly, the monolithic sputtering target assembly can have the overall same shape as any conventional sputtering target assembly wherein a target blank is bonded onto a backing plate. Examples of such designs and/or descriptions of such sputtering target assemblies can include, for instance, those designs and descriptions found in the following U.S. Patents and Publications: U.S. Pat. Nos. 4,198,283; 5,456,815; 5,392,981; 5,262,030; 5,487,823; 5,667,665; 5,630,918; 5,753,090; 5,772,860; 6,085,966; 6,210,634; 6,235,170; 6,261,984; 6,274,015; 6,299,740; 6,319,368; 6,334,938; 6,395,146; 6,402,912; 6,409,965; 6,417,105; 6,419,806, wherein all of these patents and publications are incorporated in their entirety by reference herein and form a part of the present application. Certainly, the commercially available shapes and sizes of targets and assemblies thereof can be used in the present invention.

In an optional embodiment of the present invention, the monolithic sputtering target assembly can have a flange portion wherein a portion (e.g., around the target blank portion) of the flange is used to connect or hold in place the overall sputtering target assembly during the sputtering or erosion process. This flange portion can have different properties from the remaining portion of the monolithic sputtering target assembly. For instance, the flange portion can have a different yield strength/rigidity. This can be quite advantageous since the flange portion, as indicated above, is used to hold in place the overall sputtering target assembly during the sputtering process. Therefore, if the flange portion can be made more rigid and/or have a higher yield strength, this is quite beneficial. Thus, the flange portion of the monolithic sputtering target assembly may not be fully recrystallized while the remaining portion of the monolithic sputtering target assembly is fully recrystallized or is at least partially recrystallized. Also, the flange portion can have a different purity, texture, and/or grain size depending upon the various advantages desired in the overall monolithic sputtering target assembly.

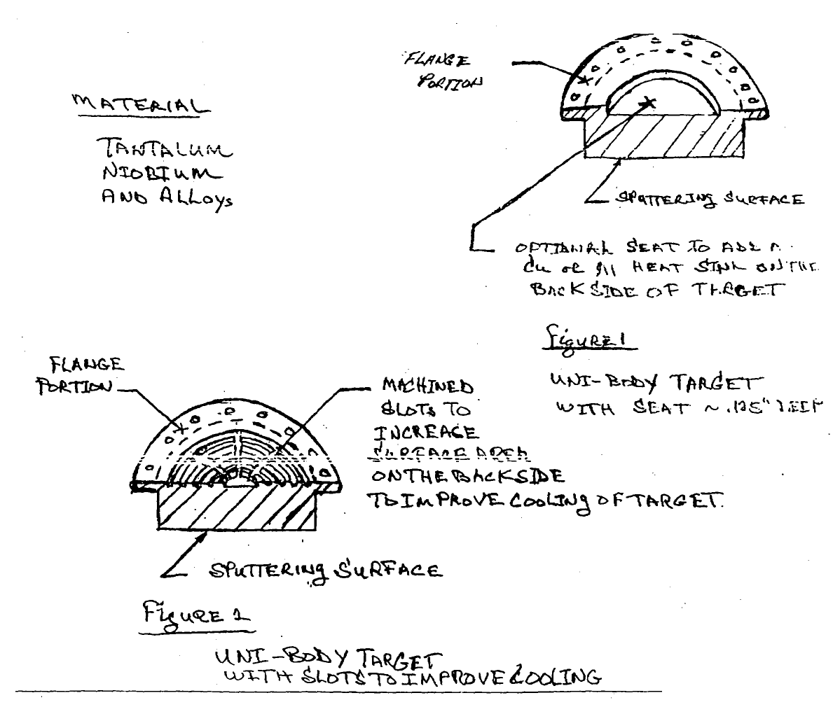

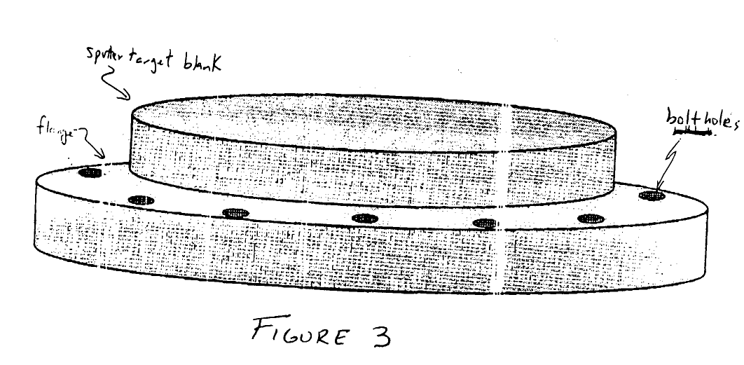

Optionally, the monolithic sputtering target assembly of the present invention can have a heat sink configuration on the underneath side of the target assembly. This provides an improved mechanism to improve cooling of the target during the sputtering process. One such way to create a heat sink configuration is to create slots or grates in the underneath side of the target assembly such as shown in FIG. 2. Typically, the slots are away from the flanged portion of the overall target assembly or are directly underneath the sputtering target blank surface of the target assembly. In the alternative, a seat or recessed portion can be created away from the flanged portion and directly underneath the sputtering target blank surface to provide an area to add a heat sink on the back side of the target assembly. This heat sink can be of any material such as copper, aluminum alloys thereof, or the like. This optional heat sink can be attached by any means such as by fastening devices such as screws, clamps and the like, mechanical means such as interference fitting or threading onto the backing plate; bonding media such as by soldering, brazing, or diffusion bonding; or bonding methodologies such as Electron Beam (EB) welding, inertia welding, frictional stir welded, and the like. The seat or recessed portion can be any depth such as from about 0.05 inches deep to about 0.5 inches or more. This optional seat can typically have the same dimensions of the actual sputtering target blank surface that forms part of the monolithic sputtering target assembly such as shown in FIG. 1. Alternatively, this seat can have a smaller configuration.

The monolithic sputtering target assembly can be formed in many ways. For instance, the monolithic sputtering target assembly can be formed by taking a plate or billet of sufficient thickness. Typically, the thickness of the plate or billet has a thickness that is the same or greater than the greatest thickness of the overall target assembly. This plate or billet of any purity, can then be properly worked or deformed to create the desired texture and/or grain size as shown, for instance, in WO 00/31310. Then, the flanged portions and overall diameters of the target assembly can be cut from this plate or billet using standard techniques such as, but not limited to, conventional machining, grinding, Electro-Discharge Machining (EDM), abrasive-jet/water-jet cutting, and the like. The flange portions can optionally be worked or deformed to alter the properties of the flange, such as cold worked which leads to an improved yield strength and more rigidity. For example, a planar, circular sputtering target blank can be rotated about its center and have its circumferential region reduced in thickness by passing between rollers or hammers. Furthermore, the flange portion can be not recrystallized at this point. The difference in yield strength between the flange portion and the target blank portion can be 10% to 100% or more.

Afterwards, the monolithic sputtering target assembly can be subsequently treated using conventional techniques, such as machining, polishing, and surface conditioning. In another embodiment of the present invention, a sputtering target assembly can be made with a separate backing plate and a separate sputtering target blank, wherein the backing plate portion is made from one of the metals previously mentioned above and preferably a valve metal, cobalt, tungsten, or titanium, or alloys thereof and the sputtering target blank portion is made from any metal that can be sputtered. In this embodiment, preferably the backing plate and the sputtering target blank are made from the same material. More preferably, the backing plate and sputtering target blank are both made from tantalum, or are both made from niobium, or are both made from titanium, or are both made from cobalt, or are made from alloys thereof. In such an embodiment, the backing plate can be bonded onto the sputtering target blank or vice versa using standard techniques such as, but not limited to, fastening devices such as screws, clamps and the like; mechanical means such as interference fitting or threading onto backing plate; bonding media such as by soldering, brazing, or diffusion bonding; or bonding methodologies such as Electron Beam (EB) welding, inertia welding, frictional stir welded, and such. The material described above with respect to the monolithic sputtering target assembly can be used in this embodiment as well and the optional embodiment such as the heat sink configuration and the like can be used herein as well as optional embodiments.

In addition, the flange portion of the monolithic target assembly, or the flange and backing plate portions of a target assembly, can be produced from a material having a different purity, texture, and/or grain structure than the sputtering target. For instance, the flange or backing plate and flange components can be fabricated from metal powder (powder-met) having a lesser cost and/or a different chemical purity than the sputtering target. The metal powder could be consolidated using convention powder metallurgy techniques such as Hot Isostatic Pressing (HIP), press and sinter, and the like. The powder consolidation process could be used to produce a flange or a backing plate and flange portion which would then be attached to the sputtering target using means described previously. More preferably, the metal powder is consolidated to form a flange or a backing plate and flange as described above, but while in contact with the sputtering target blank portion with or without the presence of a bonding media. For example, the powder and the sputtering target can be HIPed together so the HIP process acts to both consolidate the powder into a flange or into a flange and backing plate while concurrently bonding the flange or flange and backing plate to the sputtering target blank portion.

In one embodiment of the present invention, using the sputtering target assemblies of the present invention, the fabricator can use the sputtering target assemblies of the present invention and then after the sputtering is completed a spent sputtering target assembly is formed. This spent sputtering target assembly can then be recycled to recover the material in the spent sputtering target assembly. The recycling can be accomplished a number of ways. For instance, the spent sputtering target assembly can be melted down and formed into an ingot for further processing into a new sputtering target assembly or for other uses. In addition, the spent sputtering target could be converted into a powder form. Alternatively, the spent sputtering target assembly can be recycled by filling in the cavities of the spent target blank portion with the same type of material that was sputtered. Also, the spent sputtering target assembly can be subjected to a redepositing process which redeposits new material onto the spent target such as by flame spraying, plasma jet, or Osprey processes.

The present invention further involves a method of doing business which includes providing a sputtering target assembly of the present invention to a fabricator where the sputtering target assembly is used in a sputtering process which results in the formation of a spent target assembly. Then, the amount of the target material consumed by sputtering can be determined and then the fabricator or customer or the person being charged can be charged for the amount of the target material actually consumed. This process can further include, as an option, the returning of the spent sputtering target assembly to the provider or someone else for recycling or for other uses. In this part of doing business, the fabricator is only charged for the actual amount of material sputtered or use, and any other additional charges that are part of this service. This is beneficial to the fabricator since typically in the business, spent targets are undesirable byproducts of the sputtering process which causes loss of revenue to the fabricator. The process is also beneficial to the primary metal manufacturer because it helps to assure that spent targets are returned for reprocessing. This reduces the need to mine and refine ore to replace the amount of material that would be discarded as spent sputtering targets. Thus, the present invention can be the technology equivalent to buying beverages such as a case of beer and then consuming the beer and returning the bottles to the bottler or beer manufacturer for further processing and refilling. This is quite a unique approach in this sputter field and thin film field and provides immense advantages to the fabricator and to the provider of the target and target assemblies.

As can be seen from the above, the present invention overcomes many of the disadvantages of conventional sputtering target assemblies since a uni-body sputtering target assembly or monolithic sputtering target assembly avoids the serious issue of de-bonding. In addition, contamination issues with respect to the backing plate contaminating the sputtering process or the resulting film is avoided and the need for a coating on these backing plates as accomplished by plasma or flame spraying is not necessary. Also, contamination issues caused by the backing plate material or material used to bond the backing plate onto the target blank with such substances as solder is avoided and the avoidance of these materials is quite significant when high purity materials are used since even minor contaminants can be a serious detriment to the high purity sputter material either during the sputtering process or during the process where the spent target is reclaimed and converted into high purity sputtering target material.

Also, when backing plates are used, there are contamination risks to the products being formed from the sputtering process. In more detail, when burn-through occurs during the sputtering process with conventional target assemblies using conventional backing plates, contamination immediately can occur due to the burn-through of the backing plate. With the present invention, there is no contamination risk from a burn-through. At the end of the target life of the blank in the present invention, which typically leads to burn-through, a loss of vacuum in the sputtering system occurs which leads to an immediate shut down of the process. No contamination occurs. Thus, with the present invention, many of the disadvantages are overcome.

The targets of the present invention can be used in any field that benefits from sputtering and the formation of thin films, such as, semiconductors, optics, optronics, corrosion resistance, protective coatings, superconductors, and devices thereof or components thereof.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed is:

1. A monolithic sputtering target assembly comprising a one piece assembly made from the same metal.

2. The monolithic sputtering target assembly of claim 1, wherein said metal comprises tantalum.

3. The monolithic sputtering target assembly of claim 1, wherein said metal comprises niobium.

4. The monolithic sputtering target assembly of claim 1, wherein said metal comprises cobalt.

5. The monolithic sputtering target assembly of claim 1, wherein said metal comprises titanium.

6. The monolithic sputtering target assembly of claim 1, wherein said metal comprises a valve metal.

7. The monolithic sputtering target assembly of claim 1, wherein said one piece assembly comprises a sputtering target blank portion and a backing plate portion.

8. The monolithic sputtering target assembly of claim 7, wherein said backing plate portion comprises a flange portion.

9. The monolithic sputtering target assembly of claim 7, wherein, said sputtering target blank portion is at least partially recrystallized.

10. The monolithic sputtering target assembly of claim 7, wherein said at least a portion of said backing plate portion is not recrystallized.

11. The monolithic sputtering target assembly of claim 8, wherein said flange portion has a higher yield strength and/or is more rigid than said sputtering target blank portion.

12. The monolithic sputtering target assembly of claim 1, wherein said metal has a purity of from about 99.5% or greater.

13. The monolithic sputtering target assembly of claim 1, wherein said metal has an average grain size of about 300 microns or less.

14. The monolithic sputtering target assembly of claim 1, wherein said metal has an average grain size of 100 microns or less.

15. The monolithic sputtering target assembly of claim 1, wherein said metal has an average grain size of about 25 microns or less.

16. The monolithic sputtering target assembly of claim 1, wherein said metal has a texture of (111) on the surface or throughout said metal.

17. The monolithic sputtering target assembly of claim 1, wherein said metal has a texture of (100) on the surface or throughout said metal.

18. The monolithic sputtering target assembly of claim 1, wherein said metal has a primary or mixed (111) texture throughout said metal.

19. A sputtering target assembly comprising a backing plate and a sputtering target blank, wherein said backing plate comprises a valve metal, cobalt, titanium, or alloys thereof, and said sputtering target blank comprises a metal.

20. The sputtering target assembly of claim 19, wherein said backing plate and said sputtering target blank comprise the same metal.

21. The sputtering target assembly of claim 19, wherein said sputtering target blank and said backing plate are tantalum.

22. The sputtering target assembly of claim 19, wherein said sputtering target blank and said backing plate are niobium.

23. The sputtering target assembly of claim 19, wherein said sputtering target blank and said backing plate are titanium.

24. The sputtering target assembly of claim 19, wherein said sputtering target blank and said backing plate are cobalt.

25. A method of recycling a sputtering target comprising providing a monolithic sputtering target assembly of claim 1;
sputtering said monolithic sputtering target assembly to form a spent monolithic sputtering target assembly; and
recycling said monolithic sputtering target assembly.

26. The method of claim 25, wherein recycling comprises melting down said spent monolithic sputtering target assembly.

27. The method of claim 25, wherein said recycling involves filling in any cavities present in said spent monolithic sputtering target assembly.

28. The method of claim 25, recycling comprises redepositing metal on said spent monolithic sputtering target assembly to form a new monolithic sputtering target assembly.

29. A method of doing business comprising providing a monolithic sputtering target assembly of claim 1 to a fabricator where it is sputtered to form a spent target assembly;
determining the amount of target consumed by sputtering; and
charging said fabricator or customer for the amount of target consumed.

30. The method of claim 29, further comprising returning said spent target assembly to a provider.

31. The method of claim 29, further comprising recycling said spent target assembly.

32. A method of recycling a sputtering target comprising providing a sputtering target assembly of claim 19;
sputtering said sputtering target assembly to form a spent sputtering target assembly; and
recycling said sputtering target assembly.

33. A method of doing business comprising providing a sputtering target assembly of claim 19 to a fabricator where it is sputtered to form a spent target assembly;
determining the amount of target consumed by sputtering; and
charging said fabricator or customer for the amount of target consumed.

34. The monolithic sputtering target assembly of claim 1, wherein said metal is consolidated powder metal.

35. The monolithic sputtering target assembly of claim 1, wherein said metal is an ingot derived metal.

36. The monolithic sputtering assembly of claim 1, wherein a portion of said sputtering target comprises a consolidated powder metal and another portion of said sputtering target assembly comprises ingot derived metal.

37. The monolithic sputtering target assembly of claim 1, wherein said metal has a primary or mixed (111) texture and a minimum (100) texture on the surface or throughout the thickness of the sputtering target assembly, and is substantially void of (100) textural bands. throughout the thickness of the sputtering target assembly, and is substantially void of (100) textural bands.

38. The monolithic sputtering target assembly of claim 1, wherein said metal has a primary or mixed (100) texture and a minimum (111) texture on the surface or throughout the thickness of the sputtering target assembly, and is substantially void of (111) textural bands.
